(19) United States
(12) Patent Application Publication
(10) Pub. No.: US 2025/0365986 A1
(43) Pub. Date: Nov. 27, 2025

(54) THERMAL MANAGEMENT STRUCTURE FOR MEMORY STACKS ON LOGIC

(71) Applicant: INTERNATIONAL BUSINESS MACHINES CORPORATION, ARMONK, NY (US)

(72) Inventors: John W. Golz, Hopewell Junction, NY (US); John Knickerbocker, Monroe, NY (US); Mukta Ghate Farooq, Hopewell Junction, NY (US); Keiji Matsumoto, Yokohama (JP)

(21) Appl. No.: 18/674,173

(22) Filed: May 24, 2024

(51) Int. Cl. H10B 80/00; H01L 25/00; H01L 25/065; H01L 25/18

(52) U.S. Cl. CPC H10B 80/00; H01L 25/0652; H01L 25/18; H01L 25/50; H01L 2225/06589

(57) ABSTRACT

A semiconductor structure that includes a logic die, a plurality of memory die stacks located above the logic die with a plurality of gaps located between the plurality of memory die stacks, and high thermal conductive material located within the plurality of gaps.

### BACKGROUND

The present disclosure generally relates to semiconductors, and more particularly to an apparatus for heat dissipation from semiconductors.

With the onset of cloud computing, big data and other centralized high performance computing environments, system administrators are increasingly looking for new ways to pack as much functionality into as small a space as is practicable. However, increasingly difficult component integration challenges, particularly with respect to packaging and cooling, present themselves when trying to maximize functionality and minimize space consumption.

### SUMMARY

According to some embodiments of the disclosure, there is provided a semiconductor structure that includes a logic die, a plurality of memory die stacks located above the logic die with a plurality of gaps located between the plurality of memory die stacks, and high thermal conductive material located within the plurality of gaps.

According to some embodiments of the disclosure, there is provided a semiconductor structure that includes a logic die including a redistribution layer (RDL), a plurality of memory die stacks located on the RDL of the logic die with a plurality of gaps located between the plurality of memory die stacks, and high thermal conductive material located within the plurality of gaps.

According to some embodiments of the disclosure, there is provided a method of forming a semiconductor structure. The method can include providing a logic die prepared with a redistribution layer (RDL), bonding a plurality of memory die stacks to the RDL of the logic die, and providing a high thermal conductive material within a plurality of gaps located between the plurality of memory die stacks, wherein the high thermal conductive material is in contact with the RDL of the logic die.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a cross-sectional view of a semiconductor structure including thermal management structure for memory die stacks on logic, in accordance with embodiments of the present disclosure.

FIG. 2 illustrates a cross-sectional view of a step in the fabrication of the semiconductor structure of FIG. 1, in accordance with embodiments of the present disclosure.

FIG. 3 illustrates a cross-sectional view of a step in the fabrication of the semiconductor structure of FIG. 1, in accordance with embodiments of the present disclosure.

FIG. 4 illustrates a cross-sectional view of a step in the fabrication of the semiconductor structure of FIG. 1, in accordance with embodiments of the present disclosure.

FIG. 5 illustrates a cross-sectional view of a step in the fabrication of the semiconductor structure of FIG. 1, in accordance with embodiments of the present disclosure.

FIG. 6A illustrates a top-down view of the structure shown in FIG. 5 taken at line 6-6, in accordance with embodiments of the present disclosure.

FIG. 6B illustrates a top-down view of the structure shown in FIG. 5 taken at line 6-6, in accordance with embodiments of the present disclosure.

FIG. 7 illustrates a cross-sectional view of a step in the fabrication of a semiconductor structure of FIG. 9, in accordance with embodiments of the present disclosure.

FIG. 8 illustrates a cross-sectional view of a step in the fabrication of the semiconductor structure of FIG. 9, in accordance with embodiments of the present disclosure.

FIG. 9 illustrates a cross-sectional view of a semiconductor structure including thermal management structure for memory die stacks on logic, in accordance with embodiments of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to thermal regulation of semiconductor dies. More particularly, the present disclosure provides a semiconductor structure that includes thermal management structure for memory die stacks on logic, which includes a logic die, a plurality of memory die stacks located above the logic die with a plurality of gaps located between the plurality of memory die stacks, and high thermal conductive material located within the plurality of gaps. While the present disclosure is not necessarily limited to such applications, various aspects of the disclosure can be appreciated through a discussion of various examples using this context.

In conventional structures of “memory stacks on logic,” a heat spreader can be located on top of memory die stacks (otherwise referred to as “memory stacks”) that are located atop a logic die. The logic die can create an excessive amount of heat but may not be cooled efficiently by the heat spreader due to its distance from the heat spreader and due to the presence of the memory die stacks between the logic die and the heat spreader.

To address needs and challenges of cooling a logic die located below multiple memory die stacks, embodiments disclosed herein include a high thermal conductive material applied in gaps between adjacent memory die stacks in a semiconductor structure. The logic die can include a redistribution layer (RDL) between the logic die and the memory die stacks that can include a dielectric made of a high thermal conductive material, such as diamond, for example. Heat generated by the logic die can be effectively spread throughout the RDL and can then be conducted to the high thermal conductive material located in the gaps between the memory die stacks, and can further be conducted through the high thermal conductive material in the gaps upwards to a heat spreader located on top of the memory die stacks. The heat spreader, for example can be used to dissipate the heat from the semiconductor structure.

In order to form a thermal management structure for a semiconductor structure including memory die stacks on a logic die, as described herein, the logic die can be fabricated by wafer bonding and gaps between memory die stacks can be etched away, for example, by dry etching or wet etching, or a combination. The high thermal conductive material can be applied in the gaps.

Embodiments of the present disclosure can provide advantages that can be valuable to the semiconductor industry. An advantage of embodiments can include effective cooling of multiple semiconductor dies in a module. Yet another advantage can be that the thermal management structure disclosed addresses a challenge of cooling logic dies located below memory die stacks.

Embodiments of the present disclosure can include a semiconductor structure that includes a logic die, a plurality of memory die stacks located above the logic die with a plurality of gaps located between the plurality of memory die stacks, and high thermal conductive material located within the plurality of gaps. An advantage of such embodiments can include effective cooling of multiple semiconductor dies in a memory die stack or modules including multiple memory die stacks. Yet another advantage of such embodiments can be to address a challenge of effectively cooling logic dies located below memory die stacks.

Embodiments of the present disclosure can include a semiconductor structure that includes a logic die including a redistribution layer (RDL), a plurality of memory die stacks located on the RDL of the logic die with a plurality of gaps located between the plurality of memory die stacks, and high thermal conductive material located within the plurality of gaps. An advantage of such embodiments can include effective cooling of multiple semiconductor dies in a memory die stack or modules including multiple memory die stacks. Yet another advantage of such embodiments can be to address a challenge of effectively cooling logic dies located below memory die stacks.

Embodiments of the present disclosure can include a method of forming a semiconductor structure. The method can include providing a logic die prepared with a redistribution layer (RDL), bonding a plurality of memory die stacks to the RDL of the logic die, and providing a high thermal conductive material within a plurality of gaps located between the plurality of memory die stacks, wherein the high thermal conductive material is in contact with the RDL of the logic die. An advantage of such embodiments can include effective cooling of multiple semiconductor dies in a memory die stack or modules including multiple memory die stacks. Yet another advantage of such embodiments can be to address a challenge of effectively cooling logic dies located below memory die stacks.

It will be readily understood that the components of the present embodiments, as generally described and illustrated in the Figures herein, can be arranged and designed in a wide variety of different configurations. Thus, the following detailed description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment. It should be understood that the various embodiments can be combined with one another, and that any one embodiment can be used to modify another embodiment.

As used in this application and in the claims, the singular forms “a,” “an,” and “the” include the plural forms unless the context clearly dictates otherwise. Additionally, the term “includes” means “comprises.”

The term “semiconductor die” generally refers to a die having integrated circuits or components, data storage elements, processing components, and/or other features manufactured on semiconductor substrates. For example, semiconductor dies can include integrated memory circuitry and/or logic circuitry. Semiconductor dies and/or other features in semiconductor die packages can be said to be in “thermal contact” with one another if the two structures can exchange energy through heat via, for example, conduction, convection and/or radiation. A person skilled in the relevant art will also understand that the technology may have additional embodiments, and that the technology may be practiced without several of the details of the embodiments described below with reference to the figures.

As used herein, the terms “vertical,” “lateral,” “upper,” “lower,” “up,” and “down,” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

The semiconductor devices and methods for forming the same, in accordance with embodiments of the present disclosure, can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

“Electronic component” refers to any heat-generating electronic component of, for example, a computer system or other electronic system requiring cooling. By way of example, an electronic component may comprise one or more integrated circuit dies, and/or other electronic devices to be cooled, such as one or more electronics cards comprising a plurality of memory modules.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

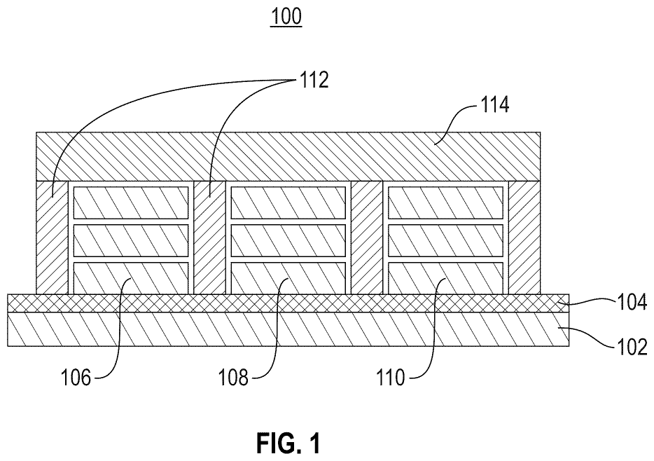

FIG. 1 illustrates a cross-sectional view of a semiconductor structure 100 including thermal management structure for memory die stacks on logic, in accordance with embodiments of the present disclosure. The semiconductor structure 100 includes a logic die 102 including a redistribution layer 104 (RDL) located on top of (atop, above, or over, etc.) the logic die 102. A plurality of memory die stacks 106, 108, 110 are located on top of (atop, above, or over, etc.) the RDL 104. In gaps (formed earlier in a process of forming the semiconductor structure 100, which is described below) between the memory die stacks 106, 108, 110, a high thermal conductive material 112 is included. A heat spreader 114 is shown located on top (atop, above, or over, etc.) of the memory die stacks 106, 108, 110 and in contact with the high thermal conductive material 112. Heat from the logic die 102 can be spread through the RDL 104 and can then be conducted upwards through the high thermal conductive material 112 to the heat spreader 114 in order to be dissipated from the semiconductor structure 100. Also, heat from the memory die stacks 106, 108, 110 can be dissipated by the heat spreader 114.

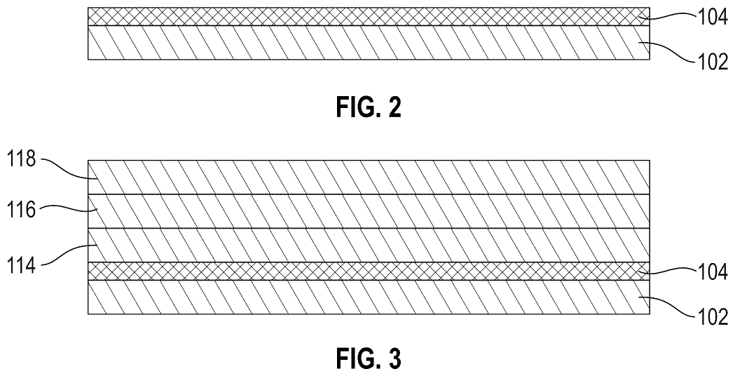

FIG. 2 illustrates a cross-sectional view of a step in the fabrication of the semiconductor structure 100 of FIG. 1, in accordance with embodiments of the present disclosure. The logic die 102 includes the RDL 104 located on top. The logic die 102 can be prepared with the RDL 104. The RDL 104 can include a dielectric material that is a high thermal conductive material, such as diamond, aluminum nitride (AlN), beryllium oxide (BeO), beryllium nitride (Be₃N₂), silicon carbide (SiC), graphite, copper (Cu), and a composite of dielectric material and metal, for example. The logic die 102 can be prepared with the RDL 104 during a grind side (back side) processing of the logic die 102 (or logic wafer), in which the logic die 102 is deposited with dielectric material prior to a through-silicon via (TSV) reveal when the logic die 102 is face down on a substrate (not shown). If the logic die 102 is face up, then the high thermal conductive material can be used in the top layers as a dielectric material. Any suitable dielectric material that has a high thermal conductivity is contemplated by the present disclosure for the RDL 104.

FIG. 3 illustrates a cross-sectional view of another step in the fabrication of the semiconductor structure 100 of FIG. 1, in accordance with embodiments of the present disclosure. After the logic die 102 and the RDL 104 are together (as shown in FIG. 2), wafer bonding can take place in order to add a plurality of memory wafers 114, 116, 118, of which three (3) are shown in the figure above the RDL 104. Any suitable number of memory wafers can be used and are contemplated by the present disclosure.

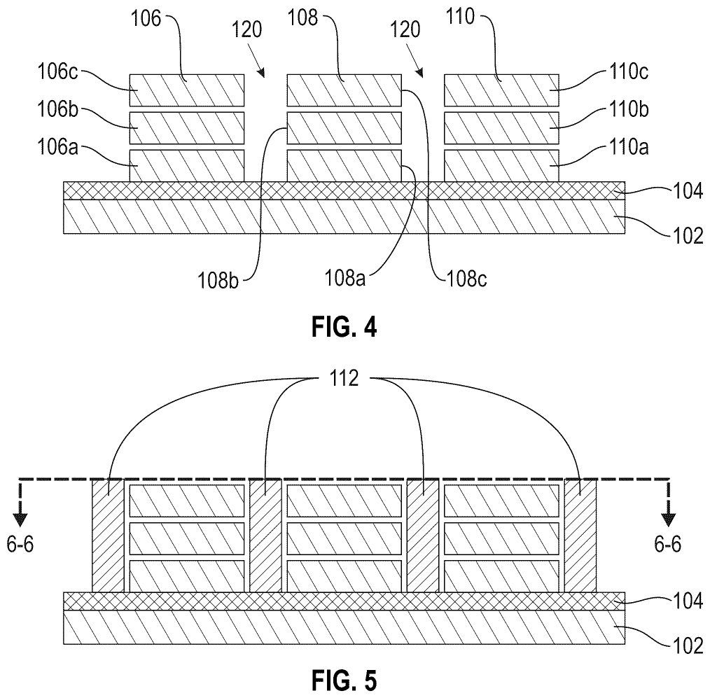

FIG. 4 illustrates a cross-sectional view of a further step in the fabrication of the semiconductor structure 100 of FIG. 1, in accordance with embodiments of the present disclosure. Once the memory wafers 114, 116, 118 are located above the RDL 104, portions or areas of the memory wafers 114, 116, 118 that do not include circuits are arranged vertically with respect to each other. Those portions of the memory wafers 114, 116, 118 can be removed to form a plurality of gaps 120 that results in formation of a plurality of separate memory die stacks 106, 108, 110 (three (3) are shown in figure). Each of the memory die stacks 106, 108, 110 includes multiple levels or dies (106a-c, 108a-c, 110a-c, respectively). The plurality of gaps 120 can be formed using selective etching processes. For example, in order to etch the gaps 120, dry etching or wet etching, or a combination of both, can be used. Also, laser ablation, plasma etching, mechanical cutting, or combinations of those can be performed in order to form the plurality of gaps 120. The etching can be followed by cleaning, such as with a liquid spray, a gas pressure nozzle and/or a vacuum suction of debris from the plurality of gaps 120. Alternate etching and/or cleaning procedures can be used. After the plurality of gaps 120 are formed there may no longer be any lateral communication between adjacent memory die stacks of the memory die stacks 106, 108, 110.

FIG. 5 illustrates a cross-sectional view of another step in the fabrication of the semiconductor structure 100 of FIG. 1, in accordance with embodiments of the present disclosure. As shown, the plurality of gaps 120 of FIG. 4 are filled with the high thermal conductive material 112. The high thermal conductive material 112 can be applied to the plurality of gaps 120 (FIG. 4) and can be made of materials such as AlN, BeO, Be₃N₂, SiC, graphite, diamond, Cu, or a composite of dielectric material and metal. For example, diamond can be deposited in the gaps 120 (FIG. 4) by chemical vapor deposition (CVD). If the memory die stacks are a few 100 micrometers (μm) in height, the plurality of gaps 120 (FIG. 4) can be filled by CVD or physical vapor deposition (PVD) processes, for example.

After the structure shown in FIG. 5, another step in the fabrication of the semiconductor structure 100 of FIG. 1 can include applying the heat spreader 114 to the top. In order to add the heat spreader 114, for example, thermal interface material (TIM) can be applied between the heat spreader 114 and the high thermal conductive material 112 in the gaps 120. Alternatively, other heat dissipating devices or components can be added, such as a heat sink, for example.

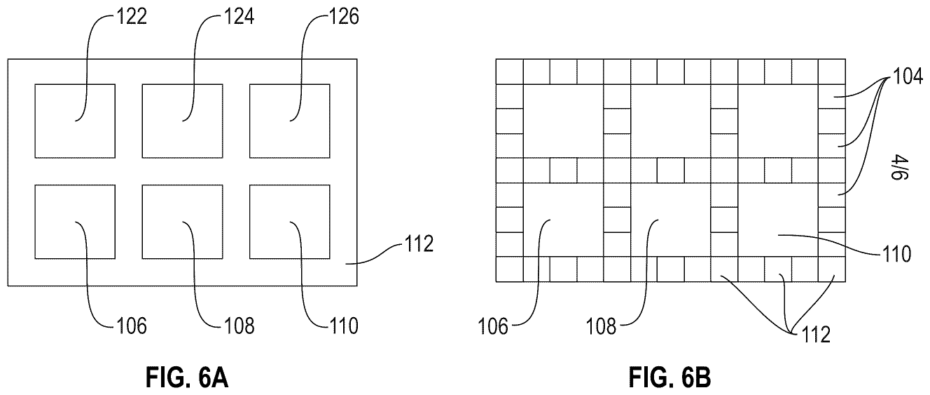

FIGS. 6A and 6B illustrate two possible, alternative top-down views of the structure shown in FIG. 5 taken at line 6-6, in accordance with embodiments of the present disclosure. FIG. 6A shows the high thermal conductive material 112 completely surrounding each of the memory die stacks 106, 108, 110 shown in the earlier figures, and in the plurality of gaps 120 between the memory die stacks, as shown in FIG. 4. The top-down view shows that in the semiconductor structure 100, there can also be additional memory die stacks 122, 124, 126 behind the memory die stacks 106, 108, 110. Any suitable number of memory die stacks can be included in the semiconductor structure 100 of the present disclosure. In FIG. 6B, the high thermal conductive material 112 forms separated columns in the gaps 120 (shown in FIG. 4). Photolithographic patterning can be one possible method to form the separated gaps in the high thermal conducive material 112 as shown in FIG. 6B. In such a method, areas where high thermal conductive material 112 would not be deposited and would be covered by resist using photolithographic patterning. Between the separated columns of the high thermal conductive material 112, the view shows the RDL 104 is visible. An advantage of the configuration including the separated columns of high thermal conducive material 112 can be that when mechanical stress is induced by a coefficient of thermal expansion (CTE) difference between silicon (Si) (or memory material) and high thermal conductive material 112, the configuration can relax the mechanical stress by reducing the volume of high thermal conductive material 112.

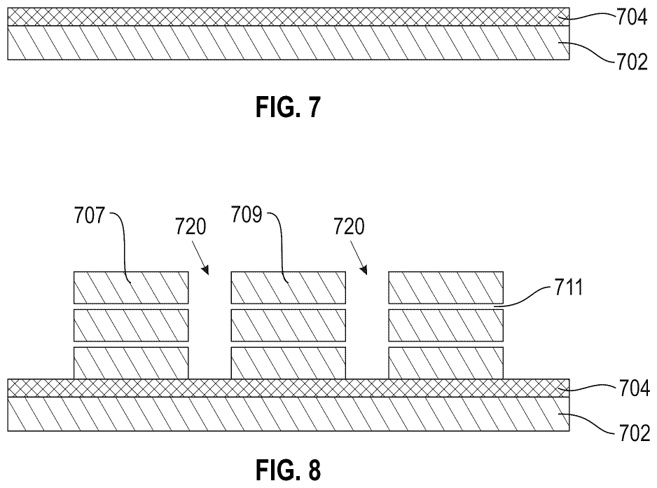

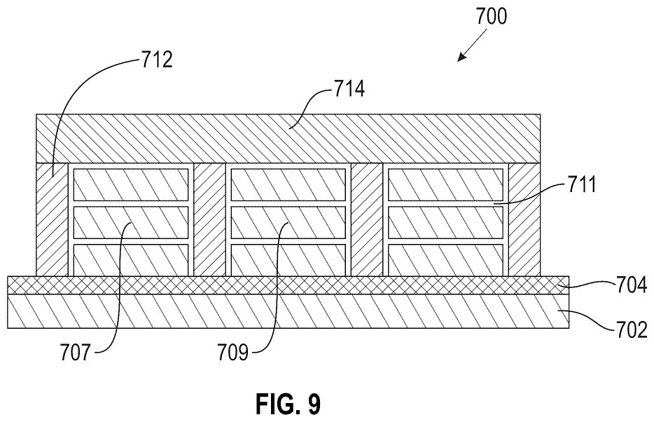

FIGS. 7-9 illustrate cross-sectional views of alternative steps in the fabrication of a semiconductor structure 700 of FIG. 9 (alternative to the steps in FIGS. 2-5 to fabricate the semiconductor structure 100 of FIG. 1), in accordance with embodiments of the present disclosure. In FIG. 7, a logic die 702 includes an RDL 704 located on top. The logic die 702 can be prepared with the RDL 704. The RDL 704 can be a dielectric that is a high thermal conductive material, such as diamond, for example. The logic die 702 can be prepared with the RDL 704 during a grind side (back side) processing of the logic die 702, in which the logic die 702 can be deposited with dielectric prior to a TSV reveal when the logic die 702 is face down on a substrate (not shown). If the logic die 702 is face up, then the high thermal conductive material can be used in the top layers as a dielectric material. Any suitable dielectric material that has a high thermal conductivity is contemplated by the present disclosure for the RDL 704.

In FIG. 8, as shown, wafer bonding can take place with individual prefabricated memory die stacks 707, 709, 711. The individual prefabricated memory die stacks 707, 709, 711 can be placed using a die to wafer (D2W) method in specific locations on the logic die 702. The individual prefabricated memory die stacks 707, 709, 711 can be placed on a backside of the logic die 702 after it has been thinned. A plurality of gaps 720 are then present between adjacent individual prefabricated memory die stacks 707, 709, 711. Any suitable number of individual prefabricated memory die stacks can be added to the logic die 702.

In FIG. 9, as shown, the plurality of gaps 720 of FIG. 8 are then filled with high thermal conductive material 712 The high thermal conductive material 712 can be applied to the plurality of gaps 720 (FIG. 8) and can be made of materials such as AlN, BeO, diamond, Cu, dielectric material, metal or a composite. For example, diamond can be deposited in the plurality of gaps 720 (FIG. 8) by CVD. If the memory die stacks 707, 709, 711 are a few 100 μm in height, the plurality of gaps 720 (FIG. 8) can be filled by CVD or PVD processes, for example. In addition, the semiconductor structure 700 of FIG. 9 includes a heat spreader 714 on top above the plurality of individual prefabricated memory die stacks 707, 709, 711 and the high thermal conductive material 712.

Calculation of thermal benefits of semiconductor structures of the embodiments of the present disclosure, which include a high thermal conductive material applied in gaps between adjacent memory die stacks where the high thermal conducive material extends between an RDL over a logic die (below the memory die stacks) and a heat spreader (above the memory die stacks), were performed. Simulations of such semiconductor structures, with four (4) memory die stacks and eight (8) memory die stacks, were performed. The conditions for the simulations included an ambient temperature of 40 degrees Celsius (° C.), a maximum chip (or die) temperature of 85° C., and a change in temperature (ΔT) of 45° C. Thermal resistance in a thickness direction (z-direction) of the semiconductor structures were used in the simulations. Thermal resistance in horizontal and vertical directions (x-direction, y-direction, respectively) were not considered. A uniform heat density, with no hot spots, was assumed.

Table 1, below, includes a result from a derivation of equivalent thermal conductivity of hybrid bonding between memory die stacks. The table includes the watts per meter Kelvin (W/mK) for two different components of the memory die stacks, which were made of Cu and silicon oxide (SiO₂). The table also includes a Cu area ratio percentage of 19.6%, which means that Cu occupies 19.6% of a total (horizontal) area and that SiO₂ occupies 80.4% of the total (horizontal) area. The result derived was about 79 W/mK.

TABLE 1
Derivation of Equivalent Thermal Conductivity of Hybrid
Bonding Interconnect Between Memory Die Stacks

| | | | Hybrid Bonding Interconnect |
|---|---|---|---|
| Cu | SiO₂ | Cu Area Ratio | Equivalent Thermal Conductivity |
| (W/mK) | (W/mK) | (%) | (W/mK) |
| 398 | 1.2 | 19.6 | 78.97 |

Table 2, below, includes results from derivation of equivalent thermal conductivity of four (4) memory die stacks. The components were back end-of-line (BEOL), with a thermal conductivity of 1 W/mK, silicon (Si), with a thermal conductivity of 148 W/mK, and the hybrid bonding interconnect, with a thermal conductivity of about 79 W/mK (from Table 1 above). The equivalent thermal conductivity of the four (4) memory die stacks was calculated to be 4.268 W/mK.

TABLE 2
Derivation of Equivalent Thermal Conductivity
of Four (4) Memory Die Stacks

| | | | | Equivalent |
|---|---|---|---|---|
| | Thermal | | Thermal | Thermal |
| | Conductivity | Thickness | Resistance | Conductivity |
| Component | (W/mK) | (mm) | (Kcm²/W) | (W/mK) |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Total | | 175 | 0.41001 | 4.268 |

Table 3, below, includes results of thermal performance of the structure of the present disclosure with four (4) memory die stacks. The structure included a thermal conductor of AlN (with a thermal conductivity of 150 W/mK). The results showed that as the area ratio of the thermal conductor increased, the maximum chip (or die) temperature decreased. As an example, an area ratio of 5% meant that AlN occupied 5% of a total (horizontal) area and a memory stack occupied 95% of the total (horizontal) area.

TABLE 3
Thermal Performance of Four (4) Memory Die Stacks

| | | | Equiv. | | | | | |
|---|---|---|---|---|---|---|---|---|
| | | | thermal | | | | | |
| | | | conductivity | Equiv. | | | | |
| | | | of 4 memory | thermal | | | | When it is |
| | | | stack with | conductivity | | Total | | transformed |
| Thermal | Thermal | Area | thermal | of 4 memory | Total | thermal | Manageable | to max. |
| conductor | conductivity | ratio | conductor | stack | thickness | resistance | heat density | chip temp. |
| material | (W/mK) | (%) | (W/mK) | (W/mK) | (mm) | (Kcm²/W) | (W/cm²) | (° C.) |
| AlN | 150 | 0 | 4.268 | 4.268 | 175 | 0.4100 | 109.754 | 85 |
| AlN | 150 | 1 | 4.268 | 5.726 | 175 | 0.3057 | 147.228 | 73.55 |
| AlN | 150 | 2.5 | 4.268 | 7.912 | 175 | 0.2212 | 203.439 | 64.28 |
| AlN | 150 | 5 | 4.268 | 11.555 | 175 | 0.1515 | 297.124 | 56.62 |

Table 4, below, includes results from derivation of equivalent thermal conductivity of eight (8) memory die stacks. The components were BEOL, with a thermal conductivity of 1 W/mK, Si, with a thermal conductivity of 148 W/mK, and the hybrid bonding interconnect, with a thermal conductivity of about 79 W/mK (from Table 1 above). The equivalent thermal conductivity of the eight (8) memory die stacks was calculated to be 4.326 W/mK.

TABLE 4
Derivation of Equivalent Thermal Conductivity
of Eight (8) Memory Die Stacks

| | | | | Equivalent |
|---|---|---|---|---|
| | Thermal | | Thermal | Thermal |
| | Conductivity | Thickness | Resistance | Conductivity |
| Component | (W/mK) | (mm) | (Kcm²/W) | (W/mK) |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Hybrid bonding | 79 | 5 | 0.00063 | |
| interconnect | | | | |
| BEOL | 1 | 10 | 0.10000 | |
| Si | 148 | 30 | 0.00203 | |
| Total | | 355 | 0.82065 | 4.326 |

Table 5, below, includes results of thermal performance of the structure of the present disclosure with eight (8) memory die stacks. The structure included a thermal conductor of AlN (with a thermal conductivity of 150 W/mK). The results showed that as the area ratio of the thermal conductor increased, the maximum chip (or die) temperature decreased.

TABLE 5
Thermal Performance of Eight (8) Memory Die Stacks

| | | | Equiv. | | | | | |
|---|---|---|---|---|---|---|---|---|
| | | | thermal | | | | | |
| | | | conductivity | Equiv. | | | | |
| | | | of 4 memory | thermal | | | | When it is |
| | | | stack with | conductivity | | Total | | transformed |
| Thermal | Thermal | Area | thermal | of 4 memory | Total | thermal | Manageable | to max. |
| conductor | conductivity | ratio | conductor | stack | thickness | resistance | heat density | chip temp. |
| material | (W/mK) | (%) | (W/mK) | (W/mK) | (mm) | (Kcm²/W) | (W/cm²) | (° C.) |
| AlN | 150 | 0 | 4.326 | 4.326 | 355 | 0.8207 | 54.835 | 85 |
| AlN | 150 | 1 | 4.326 | 5.783 | 355 | 0.6139 | 73.301 | 73.66 |
| AlN | 150 | 2.5 | 4.326 | 7.968 | 355 | 0.4456 | 100.999 | 64.43 |
| AlN | 150 | 5 | 4.326 | 11.610 | 355 | 0.3058 | 147.163 | 56.77 |

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A semiconductor structure comprising:
a logic die;
a plurality of memory die stacks located above the logic die with a plurality of gaps located between the plurality of memory die stacks; and
a high thermal conductive material located within the plurality of gaps.

2. The semiconductor structure of claim 1, further comprising:
a redistribution layer (RDL) located atop the logic die and between the logic die and the plurality of memory die stacks.

3. The semiconductor structure of claim 2, wherein the RDL includes a dielectric material.

4. The semiconductor structure of claim 2, wherein the RDL includes a material selected from a group consisting of diamond, aluminum nitride, beryllium oxide, beryllium nitride, silicon carbide, graphite, copper, and a composite of dielectric material and metal.

5. The semiconductor structure of claim 1, further comprising:
a heat spreader located above the plurality of memory die stacks and in contact with the high thermal conductive material located within the plurality of gaps.

6. The semiconductor structure of claim 1, wherein the high thermal conductive material is selected from a group consisting of aluminum nitride, beryllium oxide, beryllium nitride, silicon carbide, graphite, diamond, copper, and a composite of dielectric material and metal.

7. The semiconductor structure of claim 1, wherein the high thermal conductive material within the plurality of gaps surrounds sides of at least one of the plurality of memory die stacks.

8. A semiconductor structure comprising:
a logic die including a redistribution layer (RDL);
a plurality of memory die stacks located on the RDL with a plurality of gaps located between the plurality of memory die stacks; and
a high thermal conductive material located within the plurality of gaps.

9. The semiconductor structure of claim 8, wherein the RDL includes a dielectric material.

10. The semiconductor structure of claim 8, wherein the RDL includes a material selected from a group consisting of diamond, aluminum nitride, beryllium oxide, beryllium nitride, silicon carbide, graphite, copper, and a composite of dielectric material and metal.

11. The semiconductor structure of claim 8, further comprising:
a heat spreader located above the plurality of memory die stacks and in contact with the high thermal conductive material located within the plurality of gaps.

12. The semiconductor structure of claim 8, wherein the high thermal conductive is selected from a group consisting of aluminum nitride, beryllium oxide, beryllium nitride, silicon carbide, graphite, diamond, copper, and a composite of dielectric material and metal.

13. The semiconductor structure of claim 8, wherein the high thermal conductive material within the plurality of gaps surrounds sides of at least one of the plurality of memory die stacks.

14. A method of forming a semiconductor structure, the method comprising:
providing a logic die prepared with a redistribution layer (RDL);
bonding a plurality of memory die stacks to the RDL; and
providing a high thermal conductive material within a plurality of gaps located between the plurality of memory die stacks, wherein the high thermal conductive material is in contact with the RDL.

15. The method of claim 14, further comprising:
providing a heat spreader on top of the plurality of memory die stacks and in contact with the high thermal conductive material within the plurality of gaps.

16. The method of claim 14, wherein the providing the plurality of memory die stacks includes:
providing a plurality of memory wafers;
bonding the plurality of memory wafers; and
after the bonding, etching the plurality of gaps in the plurality of memory wafers to form the plurality of memory die stacks.

17. The method of claim 16, wherein the etching is selected from a group consisting of wet etching, dry etching and a combination of both.

18. The method of claim 14, wherein the RDL includes a dielectric material.

19. The method of claim 14, wherein the RDL includes a material selected from a group consisting of diamond, aluminum nitride, beryllium oxide, beryllium nitride, silicon carbide, graphite, copper, and a composite of dielectric material and metal.

20. The method of claim 14, wherein the high thermal conductive material located within the plurality of gaps is selected from a group consisting of aluminum nitride, beryllium oxide, beryllium nitride, silicon carbide, graphite, diamond, copper, and a composite of dielectric material and metal.
